(19) United States
(12) Patent Application Publication
(10) Pub. No.: US 2016/0204296 A1
(43) Pub. Date: Jul. 14, 2016

(54) LIQUID IMMERSING PHOTOVOLTAIC MODULE

(71) Applicant: Tianjin University, Tianjin (CN)

(72) Inventors: Li ZHU, Tianjin (CN); Yiping WANG, Tianjin (CN); Qunwu HUANG, Tianjin (CN); Jianbo REN, Tianjin (CN)

(73) Assignee: Tianjin University, Tianjin (CN)

(21) Appl. No.: 14/988,701

(22) Filed: Jan. 5, 2016

Related U.S. Application Data
(63) Continuation of application No. 13/574,600, filed on Jul. 20, 2012.

(51) Int. Cl. H01L 31/052

(52) U.S. Cl. CPC H01L 31/0521

(57) ABSTRACT

The present invention discloses a liquid immersing photovoltaic module, which comprises a baseboard, a transparent cover plate, side walls, solar cells or solar cell module and insulating liquid. The insulating liquid is inside a container formed by baseboard, cover plate and side walls. The baseboard is a transparent plate or a metal plate with fins on lower surface. The solar cells are located on the upper surface of the baseboard. The lower surface of the solar cell module is mounted on the top of a supporting board with fins, and the lower ends of the supporting board fins are installed on the top of the baseboard. This invention allows the solar cell to increase the utilization ratio of incident light, reduce the recombination of current carriers on the surface of solar cells, and increase the current output. Moreover, this invention effectively cools the front and back surfaces of solar cells and quickly removes the heat of the working solar cells, which insures the solar cells working at a fairly high efficiency, increases the durability of the solar cells and reduces the power generation cost.

### FIELD OF THE INVENTION

The present invention relates to a liquid immersing photovoltaic module and belongs to the field of photovoltaic power generation technology.

### BACKGROUND OF THE INVENTION

The efficiency of solar cell decreases with the increase of working temperature, and a solar cell may be damaged when the working temperature exceeds its tolerant threshold. Under the condition of high intensive light, the increase of the working temperature of the solar cell causes the reduction of working efficiency. Therefore, a reliable cooling system is essential to remove the heat from the solar cell and maintain a high working efficiency of the solar cell. Maintaining the solar cell under a lower working temperature is helpful for improving the power generating efficiency and the durability of the solar cell. The traditional cooling methods, comprising passive cooling and active cooling, can only cool the solar cell through the radiator installed at the backside of the cell, rather than simultaneously cool both front and back surfaces. Therefore, the efficiency of the traditional cooling method is not satisfactory. The working temperature of solar cell or solar cell module is normally high, which reduces the output of the photovoltaic power generation system and shortens the service life of the solar cell.

### SUMMARY OF THE INVENTION

The present invention aims to overcome the deficiencies of the prior art, and to provide a liquid immersing photovoltaic module.

The technical scheme of the invention is as follows:

A liquid immersing photovoltaic module comprises a baseboard, a transparent cover plate, side walls, solar cells or solar cell module and insulating liquid. The said insulating liquid is inside a container formed by the baseboard, transparent cover plate and side walls. The baseboard is made of transparent plate or metal plate with lower fins. The said solar cells are located on the upper surface of the baseboard. The lower surface of the solar cell module is fixed on the top of a supporting board with fins. The lower ends of the supporting board fins are mounted on the top of the baseboard.

The transparent cover plate and the baseboard are rectangular or geometrically similar to the photovoltaic concentrator.

The supporting board is made of copper, aluminum, stainless steel, iron or ceramic coated with copper (Direct Bonding Copper).

The fins of the supporting board are made of copper, aluminum, stainless steel, iron or ceramic coated with copper (Direct Bonding Copper).

The distance between the lower surface of the transparent cover plate and the upper surface of the baseboard is 1 mm to 50 mm.

An insulating liquid inlet and an insulating liquid outlet are arranged on the container.

The insulating liquid is deionized water, silicone oil, glycerin, ethanol, isopropyl alcohol, toluene, trichloroethane, acetone, methanol or ethylene glycol.

The present invention has the following advantages:

1. The insulating liquid directly contacts with solar cells. The Fresnel reflections of the light in the insulating liquid boundary and the multiple reflections of light inside the liquid can increase the incidence of sunlight on the surface of the solar cells.

2. The polar molecules of the insulating liquid can reduce surface recombination of carriers in the cell, which certainly increases the current output and power generation efficiency.

3. The insulating liquid is applied to remove the heat of the working cell, increase efficiency of photovoltaic power system, improve the durability of cell, thus reduce the generating cost of the photovoltaic system.

4. The supporting board is adopted to increase the cooling surface area of the solar cell module, and enhance the mechanical strength of the solar cell module.

5. The fins of the supporting board further increase the cooling area of the solar cell module and turbulent motion of the insulating liquid. Those improve the heat transfer between the solar cell module and the insulating liquid.

6. The present invention has excellent light transmittance by using transparent materials for baseboard that may be made into glass window, glass curtain wall and glass roof, in order to perfectly integrate photovoltaic technology into architectures.

7. When applying liquid immersing photovoltaic modules to a photovoltaic system, the insulating liquid inlet and outlet allow the insulating liquid to flow over the surface of the solar cell. This cools the solar cell effectively and increases the efficiency of the photovoltaic power system.

### BRIEF DESCRIPTION OF THE DRAWINGS

FIG. 1 shows the section view of the first embodiment of the present invention.

FIG. 2 shows the section view of the second embodiment of the present invention.

FIG. 3 shows the section view of the third embodiment of the present invention.

FIG. 4 shows the structural diagram of one connecting method of the present invention.

FIG. 5 shows the structural diagram of another connecting method of the present invention.

FIG. 6 shows the structural diagram of the third connecting method of the present invention.

### DESCRIPTION OF THE PREFERRED EMBODIMENTS

The following embodiments further describe the present invention, referred with the engineering drawings.

### Embodiment 1

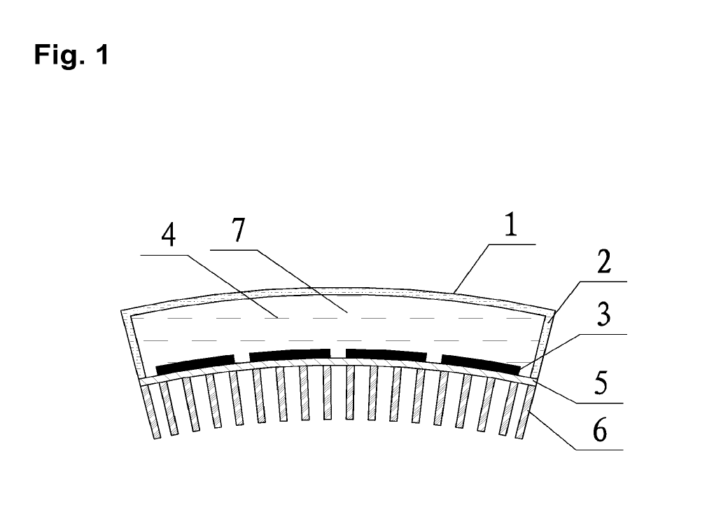

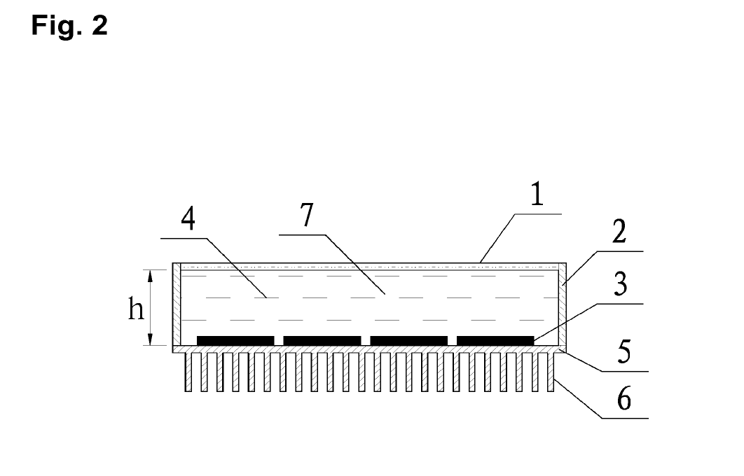

As shown in FIGS. 1 and 2, a liquid immersing photovoltaic module comprises a baseboard (5), a transparent cover plate (1), side walls (2), insulating liquid (4) and solar cells (3). The baseboard, transparent cover plate and side walls form a container (7) with insulating liquid inside. The baseboard is made of transparent plate or metal plate with lower fins (6). The solar cells are installed on the upper surface of the baseboard.

### Embodiment 2

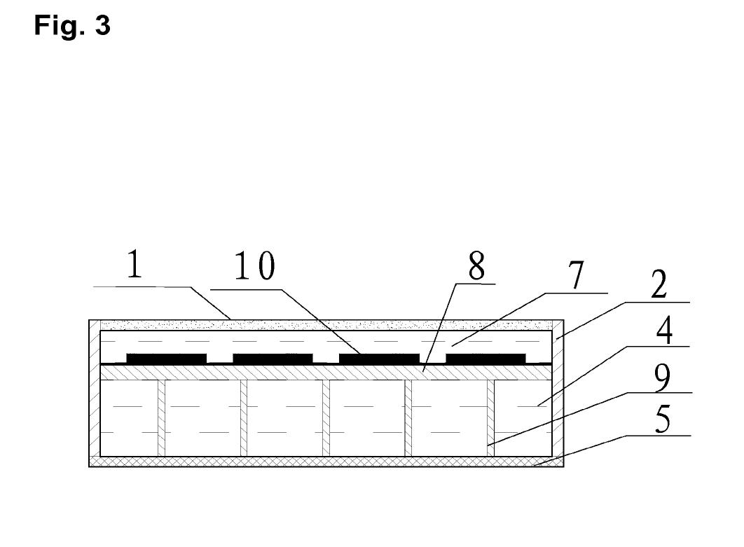

A liquid immersing photovoltaic module comprises a baseboard (5), a transparent cover plate (1), side walls (2), insulating liquid (4) and a solar cell module (10). The baseboard, cover plate and side walls form a container (7) with insulating liquid inside. The baseboard is made of transparent plate or metal board with lower fins (6). The lower surface of the solar cell module is installed on a supporting board (8) with fins (9). The lower ends of the supporting board fins are mounted on the baseboard. The supporting board is made of copper, aluminum, stainless steel, iron or ceramic coated with copper (Direct Bonding Copper). The material of the supporting board fins is copper, aluminum, stainless steel, iron or ceramic coated with copper (Direct Bonding Copper) (See FIG. 3).

The distance between the lower surface of the transparent cover plate and the upper surface of the baseboard is 1 mm to 50 mm.

An inlet and an outlet of insulating liquid are arranged on the container surface. The transparent cover plate and baseboard are rectangular or geometrically similar to photovoltaic concentrator. The cover plate and the baseboard may be rectangular when the concentrator is trough collector; or they are either dish paraboloid or rectangular when the concentrator is parabolic dish concentrator.

The insulating liquid may be statically sealed inside the container, or run through the inlet and outlet to remove the heat generated by the working solar cells or solar cell module.

The insulating liquid is deionized water, silicone oil, glycerin, ethanol, isopropyl alcohol, toluene, trichloroethane, acetone, methanol or ethylene glycol.

The side walls are made of transparent or opaque material.

The solar cell is mounted on the upper surface of the baseboard, by adhesive bonding, welding or mechanical connection. Besides, the solar cells can also be directly deposited on the upper surface of the baseboard.

The fins and the supporting board can be made into one-piece structure, or the individual fins are glued, welded or mechanically installed on the underside of the supporting board.

Based on the width of the liquid immersing photovoltaic module, the number of liquid inlet and outlet can be correspondingly null, one or two pairs, or a plurality of liquid inlet and outlet.

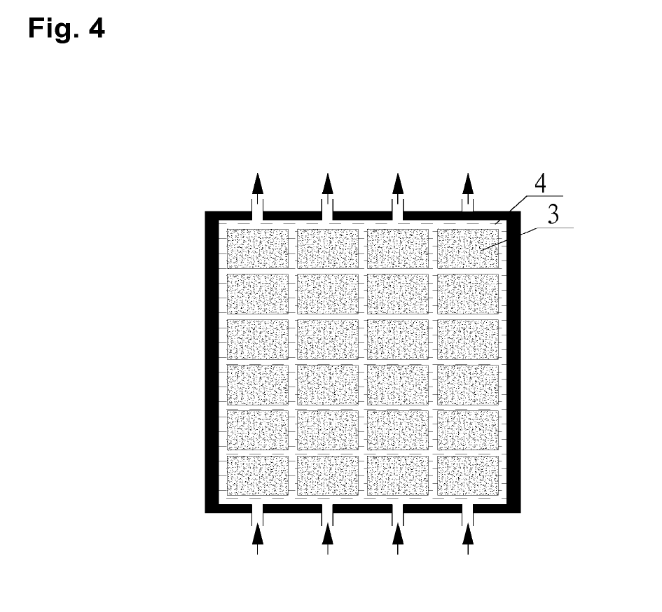

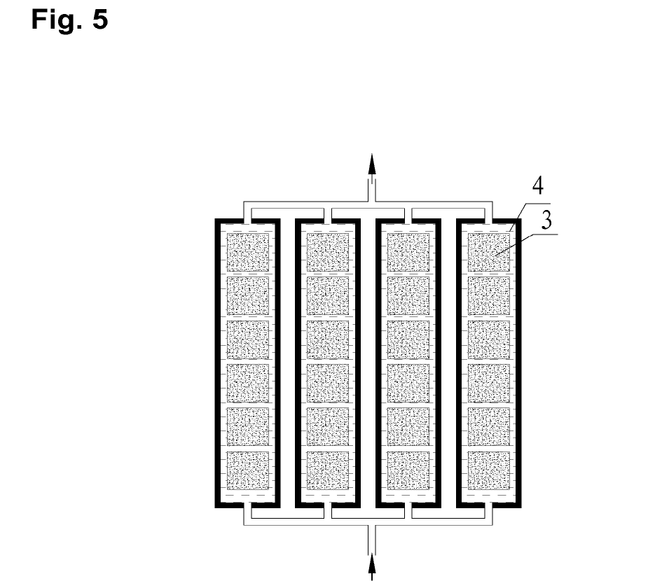

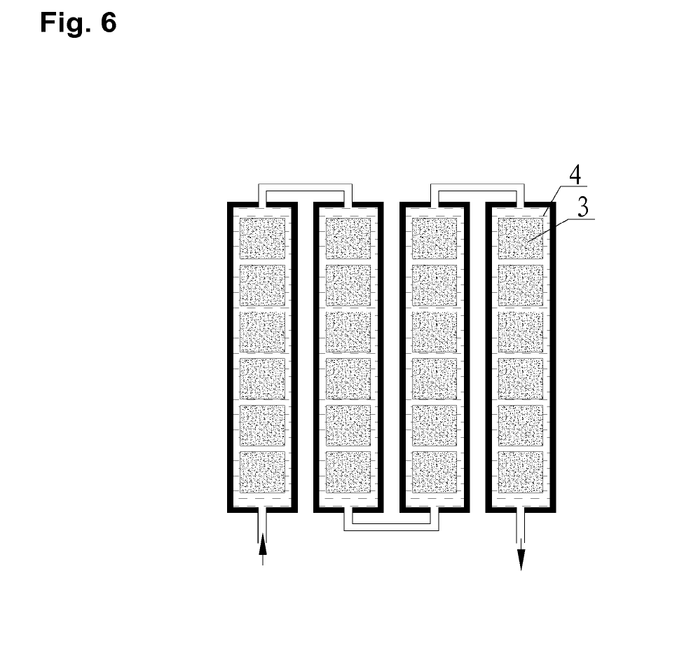

The liquid inlet and outlet can be connected in series or parallel form, as shown in FIG. 4, FIG. 5 and FIG. 6.

1. A liquid immersing photovoltaic module comprises a baseboard, a transparent cover plate, side walls, solar cells or solar cell module and insulating liquid; the baseboard, cover plate and side walls form a container to hold the insulating liquid; the baseboard is a transparent plate or a metal plate with lower fins; the solar cells are located on the upper surface of the baseboard; the lower surface of the solar cell module is fixed on the top of a supporting board with fins, and the lower ends of the fins are fixed on the top of the baseboard.

2. The liquid immersing photovoltaic module according to claim 1, wherein the transparent cover plate and the baseboard are rectangular or geometrically similar to photovoltaic concentrator,

3. The liquid immersing photovoltaic module according to claim 1, wherein the supporting board is made of copper, aluminum, stainless steel, iron or ceramic coated with copper (Direct Bonding Copper).

4. The liquid immersing photovoltaic module according to claim 1, wherein the material of the supporting board fins is copper, aluminum, stainless steel, iron or ceramic coated with copper (Direct Bonding Copper).

5. The liquid immersing photovoltaic module according to Claims 1 for 2, wherein the distance between the lower surface of the cover plate and the upper surface of the baseboard is 1 mm to 50 mm.

6. The liquid immersing photovoltaic module according to claim 1, wherein an inlet and an outlet of insulating liquid are arranged on the container.

7. The liquid immersing photovoltaic module according to claim 1 or claim 6, wherein the insulating liquid is deionized water, silicone oil, glycerin, ethanol, isopropyl alcohol, toluene, trichloroethane, acetone, methanol or ethylene glycol.
